(19) United States
(12) Patent Application Publication
(10) Pub. No.: US 2007/0051942 A1
(43) Pub. Date: Mar. 8, 2007

(54) Etch masks based on template-assembled nanoclusters

(75) Inventors: Simon Anthony Brown, Christchurch (NZ); James Gordon Partridge, Christchurch (NZ)

Correspondence Address: DANN, DORFMAN, HERRELL & SKILLMAN, 1601 MARKET STREET, SUITE 2400, PHILADELPHIA, PA, 19103-2307, US

(73) Assignee: NANOCLUSTER DEVICES LIMITED, Christchurch (NZ)

(21) Appl. No.: 10/573,123

(22) PCT Filed: Sep. 23, 2004
(86) PCT No.: PCT/NZ04/00230

§ 371 Date: Nov. 13, 2006

(30) Foreign Application Priority Data
Sep. 24, 2003 (NZ) 528448

(51) Int. Cl. H01L 51/00; H01L 21/00

(52) U.S. Cl. 257/40; 438/1; 977/900; 977/700

(57) ABSTRACT

Nanoscale or mesoscale structures are fabricated on the surface of a substrate (e.g. silicon) by the aggregation of atomic clusters (e.g. antimony or bismuth) into V-grooves. These structures, preferably in the form of nanowires, are used as etching masks for the subsequent etching of the substrate. In an embodiment the V-grooves are metallised (e.g. with titanium or gold) prior to the deposition of the clusters. In this case the use of the nanostructures (e.g. antimony or bismuth) as an etching mask results in the formation of nanostructures of the underlying metal (e.g. titanium or gold). In this way the dimensions of the nanowires are transferred into the underlying metal film and the method allows fabrication of nanowires from materials (e.g. titanium or gold) that cannot be deposited as clusters.

### FIELD OF THE INVENTION

The present invention relates to a method of preparing a pattern of a semiconductor or a metal on the surface of a substrate by employing a cluster-assembled mask for use in an etching process. More particularly but not exclusively the invention relates to a method of preparing such patterns as wires, both on the nanoscale, and up to the micron scale.

### BACKGROUND TO THE INVENTION

Nanotechnology has been identified as a key technology for the 21st century. This technology is centred on an ability to fabricate electronic, optical and opto-electronic devices on the scale of a few billionths of a metre. In the future, such devices will underpin new computing and communications technologies and will be incorporated in a vast array of consumer goods.

There are many advantages of fabricating nanoscale devices. In the simplest case, such devices are much smaller than the current commercial devices (such as the transistors used in integrated circuits) and so provide opportunities for increased packing densities, lower power consumption and higher speeds. In addition, such small devices can have fundamentally different properties to those fabricated on a larger scale, and this then provides an opportunity for completely new device applications.

One of the challenges in this field is to develop nanostructured devices that will take advantage of the laws of quantum physics. Electrical devices with dimensions of ˜100 nm that operate on quantum principles (such as single electron transistors and quantum wires) have generally been proven at only low temperatures (<−100° C.).

The challenge now is to translate these same device concepts into structures with dimensions of only a few nanometres, since the full range of quantum effects and novel device functionalities could then be available at room temperature. Indeed, as discussed below, some prototype nanoscale devices have been fabricated that demonstrate such quantum effects at relatively high temperatures. However, as is also discussed below, there remain many challenges to overcome before such devices find commercial applications.

In general, there are two distinct approaches to fabricating nanoscale devices:
‘top-down’, and
‘bottom up’.

In the ‘top-down’ approach, devices are created by a combination of lithography and etching. The resolution limits are determined by, for example, the wavelength of light used in the lithography process: lithography is a highly developed and reliable technology with high throughput but the current state of the art (using UV radiation) can achieve devices with dimensions ˜10 nm only at great expense. Other lithography techniques (e.g. electron beam lithography) provide (in principle) higher resolution but with a much slower throughput.

The ‘bottom-up’ approach proposes the assembly of devices from nanoscale building blocks, thus immediately achieving nanoscale resolution, but the approach usually suffers from a range of other problems, including the difficulty, expense, and long time periods that can be required to assemble the building blocks. A key question is whether or not the top-down and bottom-up approaches can be combined to fabricate devices which take the best features of both approaches while circumventing the problems inherent to each approach.

Examples of the prior art relating to cluster devices have been discussed in Refs 1-40 of NZ Provisional Specification 524059 and in Refs 1-37 of PCT Application NZ02/00160. These are taken to be included here.

General descriptions of optical lithography are available in many text books (e.g. [1]). At its most basic level optical lithography consists of
Exposure of a resist-coated substrate to light through a mask
Development of the resist in order achieve the transfer of the pattern on the mask into the resist layer
Etching so as to transfer the pattern into the substrate
Removal of the remaining resist.

The chief limitation in this process is that the use of light to expose the resist limits the resolution that can be achieved, since light can usually only be focussed to a spot with diameter ˜λ/2. Various alternative techniques have been used, including
electron beam lithography[2], which can achieve high resolution but is inherently slow because it is a sequential write process
nanoimprint lithography [3,4,5,6], which can achieve high resolution but is a relatively new technique that is unproven in industrial settings. Contact between a mold and the substrate may be disadvantageous since dust or other extraneous material can damage the mold or prevent pattern transfer.

### OBJECT OF THE INVENTION

It is an object of the invention to provide a method of preparing nanoscale or up to micronscale patterns, particular wire-like structures on the surface of a substrate, and/or devices formed therefrom which overcome one or more of the abovementioned disadvantages, or which at least provide the public with a useful alternative.

### SUMMARY OF THE INVENTION

According to a first aspect of the invention there is provided a method of forming a pattern on or in a substrate surface comprising or including the steps of:
a) Providing a substrate;
b) modifying the substrate surface to provide a topographical feature, or identifying a topographical feature on the substrate surface;
c) preparing a plurality of particles;
d) deposition of a plurality of the particles on the substrate surface in, or in the general vicinity of, the topographical feature;
e) formation of an arrangement of particles via accumulation (by one means or another), of the particles, into or against or proximal to, the topographical feature;
f) removing at least a portion of the substrate by etching, the arrangement of particles acting as an etch mask.

Preferably the substrate is at least partially an insulating or semiconducting material.

Preferably the pattern is in the form of a wire; the arrangement of particles being a substantially continuous chain of metallic clusters.

Preferably the wire is a nanowire and the particles are nanoparticles.

Preferably the modification includes formation of a step, depression or ridge in the substrate surface.

Preferably the modification comprises formation of a groove having a substantially v-shaped cross-section or inverted pyramid structure running substantially between the contacts.

Preferably the surface modification involves lithography.

Preferably the surface modification step involves the use of etching and takes advantage of the different etch rates of crystallographic planes in the substrate material.

Preferably the particles are sized between 0.5 nm and 100 microns and will give rise to a wire of dimensions between 0.5 nm and 100 microns.

Preferably the particles are composed of two or more atoms, which may or may not be of the same element.

Preferably the accumulation of particles into or against or proximal to, the topographical feature relies upon the diffusion, sliding, bouncing or other movement of the particles across or on the surface of the substrate or any material deposited on the substrate.

Preferably the substrate is substantially entirely an insulating or semiconductor material.

Preferably the etching step removes substantially all of the substrate other than the masked portion thereby leaving a free-standing wire or bridge.

Preferably the substrate is an insulating or semiconductor material with one or more surface coatings selected from one or more of a metallic and/or insulating and/or semiconducting material, and wherein one of more of the surface coatings may have been deposited before or after step b) of modifying the substrate surface.

Preferably the etching step removes substantially entirely all of one or more of the one or more surface coatings other than the masked portion.

Preferably the substrate comprises an insulating or semiconductor material coated with one or more metallic and/or semi-conducting layer(s), the metallic and/or semiconducting layer(s) being crystalline, nano- or micro-crystalline, or amorphous.

Preferably the metallic and/or semiconducting layer(s) are formed by cluster deposition of a plurality of clusters, prior to and having a different identity to, the plurality of particles formed and deposited in steps c) and d).

Preferably the metallic and/or semi-conducting layer(s) are homogeneous.

Preferably the metallic and/or semi-conducting layer(s) are not homogeneous.

Preferably the method may also include treatment of the substrate surface such as by passivation, or adding an insulating layer such as SiOx or SiN, at some point prior to any coating of the substrate with the one or more metallic and/or semiconducting layers.

Preferably the method may also include coating of the substrate surface such as by adding an insulating layer such as SiOx or SiN, or different semi-conducting layer, for the purpose of electrical insulation or prevention of oxidation of the metal or semi-conducting layer, at some point subsequent to the substrate being coated with the one or more surface coatings selected from one or more of a metallic and/or insulating and/or semiconducting material.

Preferably the method also includes an additional lithography step or steps to provide electrical contact to the pattern.

Preferably the additional lithography step or steps is/are subsequent to step f).

Preferably lithography is used to form two contacts which are separated by a distance smaller than 100 microns.

Preferably the contacts are separated by a distance less than 1000 nm.

Preferably the particles are metallic clusters.

Preferably the particle/nanoparticle preparation and deposition steps are via inert gas aggregation, or magnetron sputtering and aggregation, or other similar cluster preparation method, and the nanoparticles are atomic clusters made up of a plurality of atoms which may or may not be of the same element.

Preferably the semiconductor or insulator of the substrate is selected from silicon, silicon nitride, silicon oxide, aluminium oxide, indium tin oxide, germanium, gallium arsenide or any other III-V semiconductor, quartz, or glass.

Preferably the one or more surface coating is/are selected from one or more of aluminium, silicon, platinum, palladium, germanium, silver, gold, copper, iron, nickel or cobalt.

Preferably the nanoparticles are selected from one or more of bismuth, antimony, aluminium, silicon, platinum, palladium, germanium, silver, gold, copper, iron, nickel or cobalt clusters.

Preferably the angle of incidence of the deposition of clusters onto the substrate or the angle of the topographical feature(s) on the substrate is controlled so as to affect the density of particles or their ability to slide, stick or bounce, in or on any part or parts of the substrate.

Preferably the kinetic energy of the particles to be deposited on the substrate is controlled by the gas pressures and nozzle diameters of an inert gas aggregation source, or magnetron sputtering and aggregation, or other similar cluster source, and/or associated vacuum system.

Preferably the conditions are such to encourage diffusion of the nanoparticles on the substrate surface, including one or more of the conditions of temperature, surface smoothness and/or surface type and/or identity.

Preferably prior to deposition, one or more of the following processes may occur:
ionisation of particles,
size selection of particles,
acceleration and focussing of clusters,
the step of oxidising or otherwise passivating the surface of the v-groove (or other template) so as to modify the subsequent motion of the incident particles,
selection of particle and substrate materials and particles' kinetic energy so as to cause the particle to bounce off a part of the substrate (for example the unmodified areas between surface modifications), thereby preventing the adherence of particles in that area of the substrate,
selection of size of surface modification (e.g. width of V-groove) and so as to control the thickness of the wire formed.

Preferably the etching step f) results in removal of the substrate material and some or all of any coating materials (if present) in preference to the arrangement of particles.

Preferably the etching step f) results in removal of the non-masked coating material in preference to the substrate material.

Preferably the etching step is a plasma etching process.

Preferably the method further includes the step of:
g) removing the etch mask.

Preferably the substrate contains multiple layers of material, prepared for example by molecular beam epitaxy or metal-organic chemical vapour deposition, such that an anisotropic etching step f) results in formation of a wire in one or more of those layers of material, even in the absence of step g).

According to a second aspect of the invention there is provided a metallic or semi-conducting pattern on the surface of a substrate prepared substantially according to method described above.

According to a third aspect of the invention there is provided a method of fabricating a device including or requiring a conduction path between two contacts formed on a substrate surface, comprising or including the steps of:
A. preparing a conducting pattern between two contacts according to a method comprising or including the steps of:
   i. providing a semiconducting or insulating substrate;
   ii. modifying the substrate surface to provide a topographical feature, or identifying a topographical feature on the substrate surface;
   iii. preparing a plurality of clusters;
   iv. deposition of a plurality of the clusters on the substrate surface in, or in the general vicinity of, the topographical feature;
   v. formation of an arrangement of clusters via accumulation (by one means or another), of the clusters, into or against or proximal to, the topographical feature;
   vi. subjecting the substrate and arrangement to an etching process, the arrangement of clusters acting as an etch mask
   wherein either prior to or after step ii. one or more metallic or semiconducting layers are deposited on the substrate surface, such that the etching process removes substantially all of the one or more metallic or semiconducting layers other than the masked portion, and
   wherein the process also includes, at any stage, a step of providing electrical contacts on the substrate so that once etching is complete a conducting pattern exists between the contacts; and
B. incorporating the contacts and wire into the device.

Preferably the device includes two or more contacts and the conducting pattern is a conducting wire.

Preferably the device is a nanoscale device, and the wire is a nanowire.

Preferably there is an additional step in A of removing the etch mask at some point following the etching process.

According to a further aspect of the invention there is provided a device including or requiring a conduction path between two contacts formed on a substrate surface prepared substantially according to the method described above.

According to a further aspect of the invention there is provided a metallic or semi-conducting pattern on the surface of a substrate substantially as described herein with reference to any one or more of the Figures and or Examples.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting.

### DEFINITIONS

“Nanoscale” as used herein has the following meaning—having one or more dimensions in the range 0.5 to 1000 nanometres.

“Nanoparticle” as used herein has the following meaning—a particle with dimensions in the range 0.5 to 1000 nanometres, which includes atomic clusters formed by inert gas aggregation or otherwise.

“Particle” as used herein has the following meaning—a particle with dimensions in the range 0.5 nm to 100 microns, which includes atomic clusters formed by inert gas aggregation or otherwise. Atomic clusters could include a wide range of clusters such as but not limited to metallic, semiconducting, and insulating clusters.

“Wire” as used herein has the following meaning—a continuous (or near continuous) semiconductor or metal layer or pathway.

“Mask” as used herein has the following meaning a pathway formed by the assembly particles (which may range in size from 1 nm to 100 microns). It is not restricted to a single linear form but may be direct, or indirect. It may also have side branches or other structures associated with it. The particles may or may not be partially or fully coalesced. The definition of wire may even include a film of particles which is homogeneous in parts but which has a limited number of critical pathways; it does not include homogeneous films of particles or homogeneous films resulting from the deposition of particles. The definition of wire includes wires which have a diameter larger than the diameter of the clusters used to form it, and includes wires in which substantial numbers of clusters may be identified (partially coalesced or not) across the width of the wire

“Nanowire” a wire (as defined above) with overall dimensions of order 1000 nm which may be comprised of clusters of order 20 nm).

“Contact” as used herein has the following meaning—an area on a substrate, usually but not exclusively comprising an evaporated metal layer, whose purpose is to provide an electrical connection between the nanowire or cluster deposited film and an external circuit or an other electronic device.

“Atomic Cluster” or “Cluster” as used herein has the following meaning—a nanoscale aggregate of atoms formed by any gas aggregation or one of a number of other techniques [7] with diameter in the range 0.5 nm to 1000 nm, and typically comprising between 2 and 10⁷ atoms.

“Substrate” as used herein has the following meaning—an insulating or semiconducting material comprising one or more layers which is used as the structural foundation for the fabrication of the device. The substrate may be modified by the deposition of electrical contacts, by doping or by lithographic processes intended to cause the formation of surface texturing.

“Conduction” as used herein has the following meaning—electrical conduction which includes ohmic conduction but excludes tunnelling conduction. The conduction may be highly temperature dependent as might be expected for a semi-conducting nanowire as well as metallic conduction.

“Chain” as used herein has the following meaning—a pathway, linkage, or other structure made up of individual units which may be part of a connected network. Like a nanowire it is not restricted to a single linear form but may be direct, or indirect. It may also have side branches or other structures associated with it. The nanoparticles may or may not be partially or fully coalesced, so long as they are able to conduct. The definition of chain may even include a film of particles which is homogeneous in parts but which has a limited number of critical pathways; it does not include homogeneous films of nanoparticles or homogeneous films resulting from the deposition of nanoparticles.

“Template” A surface feature, typically created using a combination of lithography and etching, which is used to enhance the probability of formation of a wire-like structure when clusters are deposited onto the surface of the device.

“V-groove” A V-shaped trench created on the surface of a suitable substrate which acts as a template for the formation of a wire-like structure. V-groove includes other similar structures such as inverted pyramids, inverted pyramids with square bottoms, trenches with trapezoidal cross-sections.

“Diffusion” random motion of clusters across a surface.

“Sliding” directed motion of a cluster across a surface, for example when the initial momentum or kinetic energy of a cluster causes a continuation of the motion of the cluster in that direction even after contact with the surface. This may include motion in which contact with the surface is maintained, or where the cluster leaves the surface temporarily—“Bouncing”.

### BRIEF DESCRIPTION OF THE FIGURES

The invention is further described with reference to the accompanying figures:

FIG. 1. Atomic Force microscope image of a V-groove etched into silicon using KOH;

FIG. 2 Cross sectional representations of the etching steps involved in formation of a bridge structure;

FIG. 3. Atomic Force microscope images at two different resolutions of the bottom of an ‘inverted pyramid’ etched into silicon using KOH;

FIG. 4. Detailed process diagram demonstrating the production of Au/Ti nanowires using the process of the Invention;

FIG. 5. Cross-sectional diagram of a V-groove templated (a) passivated Si substrate and (b) metallised substrate, prior to cluster deposition;

FIG. 6. Sb clusters assembled at the apex of (a) a SiO₂ passivated V-groove and (b) a Ti/Au coated V-groove;

FIG. 7. FE-SEM images of Au nanowires created beneath Sb cluster assembled nanowires. The Au/Ti wire and passivated V-groove is shown in (a), (b) shows (at higher magnification) the morphology of the wire.

### DETAILED DESCRIPTION OF THE INVENTION

The present invention discloses the method of fabricating metallic or semi-conducting structures on the surface of a substrate by the assembly of particles (ideally of nanoparticles) into a particular arrangement and subsequent etching. We have disclosed previously (in application no NZ524059.) the method of preparing wires by deposition of clusters into morphological features (such as a v-groove) formed on or in a substrate. In this present invention we use these clusters as a masking device. Masking of a metal or semiconductor layer in the V-groove by the clusters allows subsequent etching to preferably achieve a wire (comprising a cluster layer on top of the metal used to coat the V-grooves). In the preferred form of the invention, further etching to remove the clusters thus yields a nanowire of the original metal that was used to coat the V-groove (in contrast our previous technique as disclosed in (application no NZ524059) could only produce a wire comprising the clusters).

The advantages of our technology (compared with many competing technologies) include that:
the formation of the cluster assembled mask does not employ high resolution optical lithography and is therefore not limited by optical diffraction
No manipulation of the clusters is required to form the mask because the wire is in “self assembled” using surface templating techniques described below.
The width of the nanowire and the mask can be controlled by the size of the cluster that is chosen.
In general, the usage of clusters in this work offers an opportunity to fabricate wires which have diameters controlled by the cluster diameter, which can be significantly smaller than dimensions achievable with lithographic processes, and may be significantly simpler.

While the formation of nanowires is emphasised herein the method of this invention is not limited to wires of nanoscale dimensions, but may also prove useful for the formation of larger wires up to 100 microns in width.

A. Method of the Invention

The preferred method invention relies upon a number of steps and/or techniques as set out below. As will be envisaged by one skilled in the art there are variants of this method (such as different order of steps, or use of different prior art processes to achieve the same ends) which will fall within the scope of the invention.
1. The formation (via lithography or other technique), or use of pre-existing, topographical features on a substrate, which will be used to guide clusters in the assembly of cluster chains (whether on the nanoscale or greater)
2. Coating the substrate with a layer of material (ideally metallic or semi-conducting)
3. the formation of particles (preferably atomic clusters), preferably on the nanoscale
4. Deposition of the particles onto the substrate. These particles may form an arrangement of particles which may for example be a continuous chain.
5. Using the arrangement of particles as an etch mask while the bulk of the metallic or semi-conducting layer of material is removed, thereby achieving a metallic or semi-conducting pattern (ideally as a wire) beneath the particle chain mask
6. Optionally removing the cluster material
7. Optionally using an additional lithography step or steps to make electrical contact to the pattern or wire.

As mentioned previously, although much of this discussion refers to nanoscale and nanoparticles, the method of the invention also includes up to the micron scale preparation of patterns. Patterns and wires of this scale may well be formed by the deposition of and masking by micron scale clusters, but equally may well be formed by the deposition of many nanoscale particles which combine to give a wire-structure on the micronscale.

1. Formation of Surface Template Structures

Electron beam lithography and photolithography are well-established techniques in the semiconductor and integrated circuit industries and currently are the preferred means of template formation. These techniques are routinely used to form many electronic devices ranging from transistors to solid-state lasers. In our technology the standard lithography processes are used to produce surface templates intended to guide clusters in the assembly of features including particularly nanowires. As will be appreciated by one skilled in the art, other techniques of the art which allow for nano-scale template formation will be included in the scope of the invention in addition to electron beam lithography and photolithography, for example nanoimprint lithography.

In conjunction with various etching techniques, this lithography, stage can be used to produce surface texturing. In particular, there are various well-established procedures for the formation of V-grooves and related structures such as inverted pyramids, for example by etching silicon with KOH. The scope of the invention includes additional lithography steps designed to achieve surface patterns which assist in the formation of nanowires.

Furthermore, the substrate may already contain pre-existing topographical features, such as steps for example. These could be taken advantage of instead of the preparation of new structures.

2. Coating the Substrate with a Layer of Material

A roughly uniform (ideally metallic or semi-conducting layer) of material coating the substrate can readily be achieved using standard techniques as would be known in the art such as thermal or electron-beam evaporation or sputtering. The metallic or semi-conducting layer of material may preferably be nano- or micro-crystalline, and may or may not be homogeneous.

Alternatively a nanocrystalline semi-conducting or metallic layer could also be formed over the V-groove by cluster deposition, and then the etch mask could be produced by deposition of clusters of a different material.

The semi-conducting or metallic layer can be deposited on top of an insulating layer such as SiOx or SiN which is grown on top of the template either in order to provide electrical isolation or to change the diffusive or sliding properties of the clusters on the surface on which they are deposited.

3. Formation of Particles

This includes the formation of atomic clusters (in the preferred form), for example by inert gas aggregation. This is the process whereby metal vapour is evaporated into a flowing inert gas stream which causes the condensation of the metal vapour into small particles. The particles are carried through a nozzle by the inert gas stream so that a molecular beam is formed. Particles from the beam can be deposited onto a suitable substrate. This process is known as inert gas aggregation (IGA), but clusters could equally well be formed using cluster sources of any other design including magnetron sputtering and aggregation for example (see e.g. the sources described in the review [7]).

4. Cluster Deposition

The basic design of a cluster deposition system is described in Ref [8] and the contents of which are hereby incorporated by way of reference. It consists of a cluster source and a series of differentially pumped chambers that allow ionisation, size selection, acceleration and focussing of clusters before they are finally deposited on a substrate. In fact, while such an elaborate system is desirable, it is not essential, and our first devices have been formed in relatively poor vacuums without ionisation, size selection, acceleration or focussing.

The acceleration of the clusters by the flowing inert gas stream through a series of nozzles determines the kinetic energy of the particles in the present experiments, although, as will be appreciated by one skilled in the art, there are many methods of controlling the kinetic energy of the particles, including the use of charged clusters and electrostatic or pulsed electric fields.

Motion of the clusters to the apex of the V-groove via diffusion bouncing or sliding leads to the eventual aggregation of the clusters into a wire-like mask.

5. Using the Chain of Particles as an Etch Mask

The chain of particles can be used as an etch mask as long as the material of the underlying semiconductor or metal layer is etched preferentially with respect to the chain of particles. Reactive ion etching is the preferred method, but wet chemical etching may be appropriate. The bulk of the metallic or semi-conducting layer of material is removed, thereby achieving a metallic or semi-conducting wire beneath the particle chain mask. In addition, removal of some or all of the substrate material in this (additional) etching step could result in a free-standing wire.

6. Possibly Removing the Particle Material

Standard wet or dry etching procedures can be used to remove the particles, so long as the etching method does not remove the underlying semiconductor or metal layer.

7. Formation of Contacts

In our technology standard lithography processes are used to produce the contacts to our devices. As will be appreciated by one skilled in the art, other techniques of the art which allow for nano-scale contact formation will be included in the scope of the invention in addition to electron beam lithography and photolithography, for example nanoimprint lithography.

B. Resultant Technologies and the Related Method

As discussed previously, it is well established that small particles can diffuse when they land on a sufficiently smooth surface. The particles diffuse until they hit a defect or another particle: for sufficiently low particle fluxes arriving at the surface, the particles aggregate at defects without significantly aggregating with each other. The present templating strategy is based on the concept that a suitable defect can be engineered to achieve cluster aggregation and ultimately form nanowire masks.

The present technology may require lithographic processing to create surface texturing. The present devices could be used for all applications previously discussed for PeCAN devices[9], but the technology allows the formation of devices with much smaller overall dimensions. Therefore The present devices are more appropriate to applications requiring a high density of devices, for example, transistors.

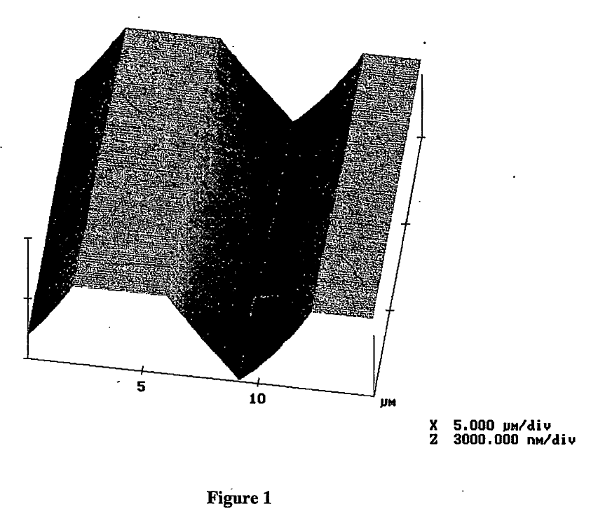

In the preferred embodiment, the invention involves using standard lithographic techniques to cause the formation of one or more V-grooves (see FIG. 1). The flat sides of the V-grooves will allow diffusion of clusters to the apex of the V-groove where they will be localised. Hence, they will gradually aggregate to form a nanowire along the bottom of the apex of the V-groove.

It is to be noted that although the V-groove texturing discussed is the preferred form of the invention, other forms of surface texturing are included in the scope of the invention.

Diffusion/Temperature Considerations

The present technology relies on surface diffusion, sliding or bouncing of the clusters for the formation of the nanowire or other structure. Temperature control of the surface can also be used to change the diffusivity of clusters, for example to allow clusters to diffuse on surfaces on which they would otherwise be immobile. (The range of temperatures which can be used is limited by the melting point of the clusters.). A variety of cluster/substrate systems may be suitable. For example, semiconductor systems such as gallium arsenide and silicon are known to be suitable for the formation of V-grooves, and it is expected that cluster materials with lattice constants different to the substrates will allow cluster diffusion, especially for small cluster sizes.

Our experimental results, discussed below, indicate that in addition to diffusion, sliding and bouncing of clusters, especially when incident at an angle which is not the normal to a V-groove facet (which is always the case for at least one of the two sides of the V-groove, since they are at an angle to each other), is important in assisting the formation of a wire-like structure at the apex of the V-groove (or other template) in the improved methodology.

C. Applications of the Invention

An important characteristic of the nanowires formed by the method of the invention is that in general they will be sensitive to many different external factors (such as light, temperature, chemicals, magnetic fields or electric fields) which in turn give rise to a number of applications. Devices of the invention may be employed in any one of a number of applications. Applications of the devices include, but are not limited to:

Transistors or Other Switching Devices.

A number of the devices described below allow switching using a mode similar to that of a field effect transistor.

Transistors formed from a combination of electron beam lithography and the placement of a single gated carbon nanotube (which simply acts as a nanowire) between electrical contacts have been fabricated by a number of groups (see e.g. [10]) and have been shown to perform with transconductance values close to those of the silicon MOSFET devices used in most integrated circuits. The present technology can be used to form an equivalent conducting nanowire between a pair of contacts. This wire can be seen as a direct replacement for the carbon nanotube in the carbon nanotube transistor. The advantage of using The present technology to form these devices is that these technologies eliminate the need to use slow and cumbersome manipulation techniques to position the nanowire.

In all cases it is critical that a third (gate) contact is provided to control current flow through the nanowire. To achieve switching the use of both top gate and bottom gate technology can be considered. However the preferred embodiment is the use of The present device with a third contact in the same plane, or close to the same plane, as the nanowire. In this case the transistor is very similar to that of the carbon nanotube transistor discussed above[10].

The preferred embodiment of this device is one in which a semiconductor layer such as silicon or germanium clusters is deposited prior to cluster deposition.

Magnetic Field Sensors.

Magnetic Field Sensors are required for a large number of industrial applications but we focus here on their specific application as a sensor for the magnetic information stored on a high density hard disk drive, or other magnetically stored information, where suitably small magnetic field sensors must be used as readheads. The principle is that the smaller the active component in the readhead, and the more sensitive, the smaller the bits of information on the hard drive can be, and the higher the data storage density.

Magnetoresistance is usually expressed as a percentage of the resistance at zero magnetic field and MR is used as a figure of merit to define the effectiveness of the readhead. Appropriate nanowires are well established as being highly sensitive to magnetic fields, i.e., large magnetoresistances (MR) can be obtained. For example, it has recently been reported that a nickel nanowire can have a MR of over 3000 percent at room temperature. [11] This far exceeds the MR of the GMR effect readhead devices currently in commercial production.

The active part of a readhead based on this technology would be a Nickel or Bismuth nanowire formed by first evaporation of a Bi or Ni layer onto a V-grooved surface and subsequent cluster deposition to form a mask layer and then etching. Note that the resolution of the readhead would be governed by the size of the nanowire and not by the overall device size (i.e. the contact size is not necessarily important) The mechanism governing the high magnetoresistances required for readheads in The present devices is likely to be spin-dependant electron transport across sharp domain walls within the wire [11] or any one of a number of other effects (or combination of these effects), such as weak or strong localisation, electron focusing, and the fundamental properties of the material from which the clusters are fabricated (e.g. bismuth nanowires are reported to have large MR values). A preferred embodiment would be that a nanocrystalline semi-conducting or metallic layer is formed over the V-groove, possibly by cluster deposition, and then the etch mask is produced by deposition of clusters of a different material.

Furthermore we note that well-defined nanowires may not be essential to the formation of a suitably sensitive readhead. Devices with more complicated cluster networks may also be useful because of the possibility of magnetic focusing of the electrons by the magnetic field from the magnetically stored information, or other magneto-resistive effects. In the case of focusing of the electrons into electrical contacts other than the source and drain and/or into deadends within the cluster network this might result in very strong modulations of the magnetoresistance (measured between source and drain) similar to those achieved in certain ballistic semi-conducting devices.

Chemical Sensors.

The devices discussed in Ref. [12] demonstrate that a narrow wire can be useful for chemical sensors, and similar chemical sensitivity should be possible due to the response of the narrow wire formed in the narrowest part of devices of the invention. It is well established that very narrow wires, i.e. with nanometre diameters, whether exhibiting quantum conductance or not, can have their conductance modulated strongly by the attachment of molecules to the surface of the wire. This may result from wave function spillage or chemical modification of the surface of the wire. The strong modulation of the conductance of the wire can lead to high chemical sensitivity.

The nanowires formed through this invention, may be useful for chemical sensing applications. These applications may be in industrial process control, environmental sensing, product testing, or any one of a number of other commercial environments. Exclusivity would be useful, i.e., it would be ideal to use a material which senses only the chemical of interest and no other chemical, but such materials are rare.

A preferred embodiment of the chemical sensing device is an array of nanowires, each formed from a different material. In this case each of the devices acts as a separate sensor and the array of sensors is read by appropriate computer controlled software to determine the chemical composition of the gas or liquid material being sensed. The preferred embodiment of this device would use conducting polymer nanoparticles formed between metallic electrical contacts, although many other materials may equally well be used.

A further preferred embodiment of this device is a nanowire which is buried in an insulating material, which is itself chemically sensitive. Chemical induced changes to the insulating capping layer will then produce changes in the conductivity of the nanowire. A further preferred embodiment of the device is the use of an insulating and inert capping layer surrounding the nanowire with a chemically sensitive layer above the nanowire, e.g., a suitable conducting polymer layer. The conducting polymer is then affected by the introduction of the appropriate chemical; changes in the electrical properties of the conducting polymer layer are similar to the action of a gate which can then cause a change in the conduction through the nanowire. Similar devices currently in production are called CHEMFETs.

Light Emitting or Detecting Devices

The devices discussed above may exploit the optical properties of the nanowire to achieve a device which responds to or emits light of any specific wavelength or range of wavelengths including ultra-violet, visible or infra-red light and thereby forms a photodetector or light emitting diode, laser or other electroluminescent device.

CCD based on silicon technology are well established as the market leaders in electronic imaging. Arrays of nanowires could equally well be useful as photodetectors for imaging purposes. Such arrays could find applications in digital cameras, and a range of other technologies.

The preferred embodiment of a photodetector based on the invention is a semiconductor nanowire, for example, a wire whose electrical conductance is strongly modulated by light, formed from silicon nanoparticles. In this regard semiconductor nanowires with ohmic contacts at each end may be appropriate, but it is perhaps more likely that wires connected to a pair of oppositely doped contacts may be more effective. The choice of the contacts (either ohmic or Schottky) will significantly influence the response of the device to light. The wavelength of light which the device responds to can be tuned by selection of the diameter of the clusters and/or cluster assembled wire. This is particularly the case for semiconductor nanoparticles where quantum confinement effects can dramatically shift the effective bandgap. Similar devices can be made to emit light. Semiconductor quantum wires built into p-n junctions (e.g. contacts 1 and 2 made to p and n type) can emit light and if built into suitable structures, lasing can be achieved

Transistor-like devices (see above) may be the most appropriate as light sensors since they are particularly suited to connection to external or other on-chip electronic circuits.

The wavelength of light which the device responds to can be tuned by selection of the diameter of the clusters forming the mask and/or the resulting nanowire. This is particularly the case for semiconductor nanoparticles where quantum confinement effects can dramatically shift the effective bandgap.

Similar devices to those discussed above can be made to emit light. Semiconductor quantum wires built into p-n junctions (e.g. contacts 1 and 2 made to p and n type) can emit light and if built into suitable structures, lasing can be achieved

Temperature Sensors.

The unusual properties of the devices may include a rapid or highly reproducible variation in conductivity with temperature, which may be useful as a temperature sensor.

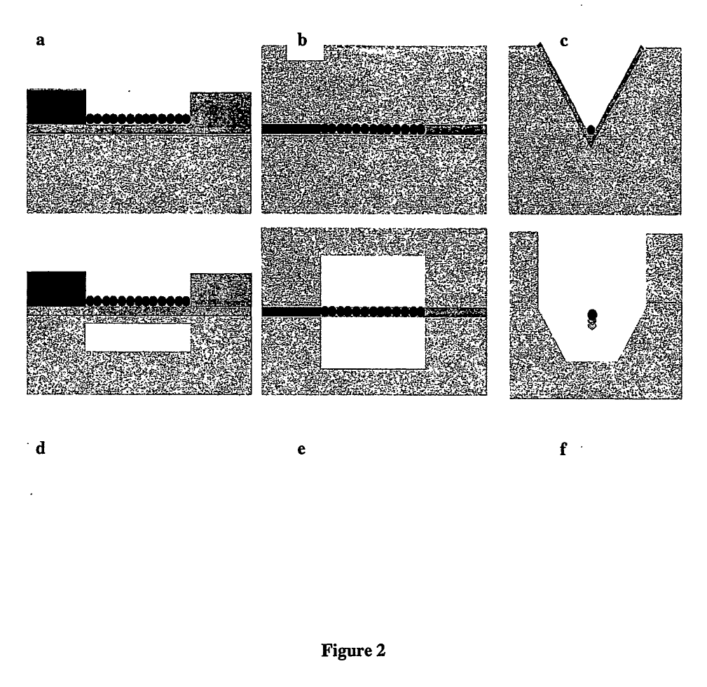

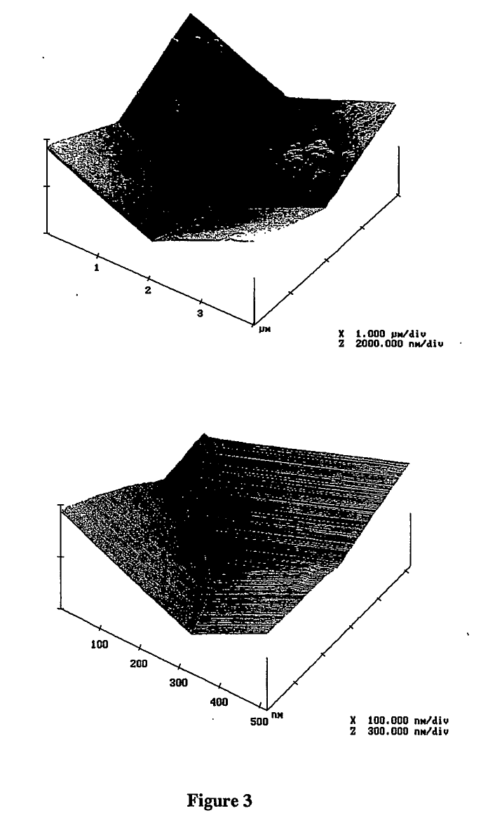

The abovementioned list of possible applications may be embodied in a number of different ways, specific examples of these include the following (which are included within the scope of the invention):
i) A device in which V-grooves or other surface templated structures are defined in the surface of a suitable semiconductor material such as silicon or GaAs (i.e. a material which has appropriately different etch rates for different crystallographic planes) in order to control the final position of deposited nanoparticles. This achieves a mask comprising a chain of clusters, or a network of clusters preferably with a narrowest point that includes a single cluster or chain of clusters, or a wire-like structure whose diameter is substantially greater than that of the individual clusters deposited. If a semiconductor or metal is chosen to coat the surface of the template, the chain of clusters can be used as an etch mask to produce a narrow wire from that semiconductor or metal. Nanoclusters can diffuse across a substrate and then line up at certain surface features[13, 14], thus generating structures resembling nano-scale wires. Nano-scale surface texturing techniques (for example v-grooves etched into the surface of a Si wafer [15], pyramidal depressions or other surface features) will force clusters to assemble into nano-scale wires. Diffusion of mobile clusters on the surfaces of the v-groove should cause the formation of a chain or wire at the apex. Similarly, sliding of the clusters under the influence of the kinetic energy with which they are incident on the surface will cause movement towards the apex of a V-groove, and changes of the angle of deposition can be used to influence the amount of sliding. The concept is that expensive and slow nanolithography processes (the ‘top-down’ approach) will be used only to make relatively large and simple electrical contacts to the device, and possibly for the formation of the v-grooves. Self assembly of nanoscale particles (the ‘bottom-up’ approach) is then used to fabricate the nanoscale etch mask. At the heart of the devices is the combination of ‘top down’ and ‘bottom up’ approaches to nanotechnology. As discussed previously, the method of this invention is not limited to wires of nanoscale dimensions, but may also prove useful for the formation of larger wires up to 100 um in width.
ii) A device as described in i in which the etching step results in removal of some or all of the original substrate material thereby leaving a substantially free-standing wire or bridge. By appropriate choice of dry or wet etching techniques, or a combination of the two, it should be possible to achieve bridge structures comprising wire-like structures of any one or more of the following materials:
   a) the original substrate material,
   b) a metallic or semiconducting layer deposited on the substrate,
   c) the deposited clusters.
The resulting bridge may therefore comprise one or more layers. This device is illustrated in FIG. 2. Representations (a) to (c) are cross-sections through a cluster assembled wire in the apex of a v-groove superimposed on a metal layer evaporated onto the substrate before etching. (a) and (c) are sections in the vertical plane, whilst (b) is in the horizontal plane. Representations (d) to (f) are the same sections following etching, showing the formation of a bridge structure comprising cluster, metal and substrate layers.
iii) A device as described in any of the above in which the etching step results in removal of the original substrate material on either side of the mask, leaving behind a ridge of the original substrate material in a approximately linear pattern similar to that of the mask. Standard dry etching processes can be used to achieve high aspect ratio structures such as that described. The cluster layer and/or any metallic or semiconducting layer deposited on the surface may or may not be removed following the creation of the ridge. In this device the objective may be to achieve a wire of the metallic or semiconducting layer deposited, or of the substrate material, or both.
iv) A device as described in any of the above in which electrical contacts are defined so as to contact the nanowire. These devices and each of the devices described below may work in an AC or DC or pulsed mode.
v) A larger device consisting of two or more of the devices described above, either to define a better or differently functioning device, or by inclusion of a percolating device of the form described in [9] to allow control of the mask/wire thickness.
vi) A device as described above which two or more contacts of equal or unequal separation are arranged in any pattern and where the contacts are of any shape including interdigitated, regular or irregular arrangements.
vii) A device in which V-grooves running between one pair of contact causes those contacts to act as ohmic contacts to the wires formed, and causes other contacts to be isolated from the wires so that they can act as gates (for example, positioned at the crests of the V-grooves). The device is then similar to a field effect transistor (FET): the voltage applied to the gate attracts (repels) electrons from the connected path thereby increasing (decreasing) the conductivity of the chain of clusters, and turning the device on (or off).
viii) A further preferred embodiment of the device described in vii) includes only a single V-groove, and thus creates a single nanowire.
ix) Further preferred embodiments of the devices described in vii) and viii) include such devices with a contact arrangement which allows ohmic contact to the nanowire formed in the bottom of the V-groove or inverted pyramid. Many such configurations can be envisaged, including single metallic contacts at each end of the V-groove, interdigitated contacts perpendicular to the V-groove, as well as metallic contacts at each corner of an inverted pyramid (See FIG. 3).
x) It is possible to create an oxide or other insulating layer on the substrate and then use lithographic techniques so as to define an area such that only clusters landing in that area participate substantially in the cluster network formed, therefore limiting the region in which the mask is formed. Only clusters landing the window (region not coated in oxide) can form a mask. In this way masks may be isolated from one another and the function of the contacts can be pre-determined. If the oxide layer covers pre-existing contacts this technique can be used to pre-determine the function of one or more contacts to be gates or ohmic contacts.
xi) Any of the devices described above which are covered entirely or partially by an oxide or other insulating layer and incorporating a top gate to control the flow of electrons through the cluster assembled structure, thereby achieving a field effect transistor or other amplifying or switching device.
xii) Any of the devices described above which are fabricated on top of an insulating layer such as SiOx or SiN which is grown on top of the template either in order to provide electrical isolation or to change the diffusive or sliding properties of the clusters on the surface on which they are deposited.
xiii) Any of the devices described above which are fabricated on top of an insulating layer which itself is on top of a conducting layer that can act as a gate, which can control the flow of electrons through the cluster assembled structure, thereby achieving a field effect transistor or other amplifying or switching device.
xiv) Any of the devices described above in which the angle of impact of the clusters on the surface of part (or parts) of the sample is chosen or controlled so as to affect the probability of a cluster sliding, bouncing or sticking to part (or parts) of the sample. This can be done by controlling either the angle of incidence relative to the entire substrate or by the angle of any template facets on the substrate.
xv) Any of the devices described above in which the kinetic energy of the clusters is controlled so as to affect the probability of a cluster sliding, bouncing or sticking to part or parts of the sample
xvi) Any of the devices described above in which switching or amplifying based on spin transport is achieved, thereby producing in a spin valve transistor.
xvii) The cluster-assembled mask may be fabricated with bismuth or antimony clusters, or equally well from any type of nanoparticle that can be formed using any one of a large number of nanoparticle producing techniques, or from any element or alloy. The nanoparticles could be formed from any of the chemical elements, or any alloy of those elements, whether they be insulating, super-conducting, semi-conducting, semi-metallic or metallic in their bulk (macroscopic) form at room temperature. The nanoparticles may be formed from a conducting polymer or inorganic or organic chemical species which is electrically conducting. Similarly the nanowire could be formed from any of the chemical elements, or any alloy of those elements, whether they be super-conducting, semi-conducting, semi-metallic or metallic in their bulk (macroscopic) form at room temperature. The nanowire may be formed from a conducting polymer or inorganic or organic chemical species which is electrically conducting. The nanowire and the cluster assembled mask materials must however be sufficiently different so as to allow the mask to not be substantially removed at the stage when the bulk of the deposited metal or semiconductor layer is removed. Similarly either or both of the contacts and/or the nanoparticles may be ferromagnetic, ferromagnetic or anti-ferromagnetic. Two or more types of nanoparticle may be used, either deposited sequentially or together, for example, semiconductor and metal particles together or ferromagnetic and non-magnetic particles together. Devices with magnetic components may yield ‘spintronic’ behaviour i.e. behaviour resulting from spin-transport. Spin-dependant electron transport across sharp domain walls within the wire [11] or between the wire and contacts can yield large magneto-resistances which may allow commercial applications in magnetic field sensors such as readheads in hard drives.
xviii) For all devices described herein, the temperature of the substrate can be controlled during the deposition process in order to control the diffusion of particles, fusion of particles or for any other reason. In general, smooth surfaces and high substrate temperatures will promote diffusion of particles, while rough surfaces and low substrate temperatures will inhibit diffusion. The fusion and diffusion of nanoparticles is material dependent.
xix) Any of the devices described above in which the film is buried in an oxide or other non-metallic or semi-conducting film to protect it and/or to enhance its properties, for example by changing the dielectric constant of the device. This capping layer may be doped by ion implantation or otherwise by deposition of dopants in order to enhance, control or determine the conductivity of the device.
xx) Any of the devices described above in which the sample is annealed either to achieve coalescence of the deposited particles or for any other reason.
xxi) Any of the devices described above in which the assembly of the nanoparticles is influenced by a resist or other organic compound, whether it be exposed, developed washed away either before or after the deposition or aggregation process.
xxii) Any of the devices described above in which the assembly of the nanoparticles is controlled or otherwise influenced by illumination by a light source or laser beam whether uniform, focussed, unfocussed or in the form of an interference pattern.
xxiii) Any of the devices described above in which the particles are deposited from a liquid, including the case where the particles are coated in an organic material or ligand.
xxiv) A device which has several contacts or ports and which relies on ballistic or non ballistic electron transport through the nanoparticles and which relies on the effect of a magnetic field to channel the electrons into an output port which was not the original output port in a zero magnetic field, or which relies on any magnetic focussing effect.
xxv) Any of the devices described above which are formed by deposition of size selected clusters or, alternatively, which are formed by deposition of particles that are not size selected.
xxvi) Any of the devices described above which are formed by deposition of atomic vapour, or small clusters, and which results in nanoparticles, clusters, filaments or other structures that are larger than the particles that were deposited.
   D. Experimental

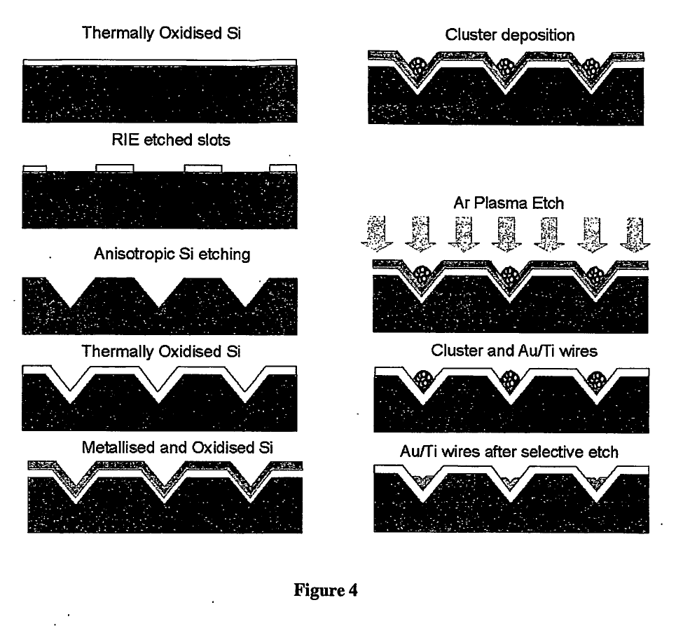

The following discloses our preferred experimental set up along with specific examples. The preferred process uses the formation of V-grooves in the substrate in order to guide the formation of nanoscale wires by accumulation clusters in the groove. A detailed process diagram demonstrating the production of Au/Ti nanowires using this preferred process of the Invention is given in FIG. 4.

Prior to cluster deposition, passivated and metallised V-grooved Si <100> substrates are prepared using standard optical lithography.

a) Lithography

Standard optical and electron beam lithography has been used to define V-grooves on silicon wafers, or silicon wafers coated with either SiOx or SiN.

b) V-Groove Formation

The following deals with the formation of a V-groove surface template on silicon, but similar approaches can be used to form other structures on other substrates.

This part of the processing begins with dicing a silicon dioxide or silicon nitride coated (layer thickness typically 120 nm) silicon wafer into 8×8 mm substrates. In order to accurately locate the orientation of the <111> plane, the oxide/nitride layer is initially dry etched through a photoresist mask to form radial slots separated by 2°. These slots are translated into V-grooves in the underlying silicon using 40% wt KOH solution. Once completed, angular alignment of the device V-groove arrays to the test slots (selecting those with the neatest etched profile) is performed through a further photolithographic and dry-etch stage. The V-groove array is formed using the same KOH solution. 2-5 um wide silicon V-grooves are produce in silicon using 40% by weight KOH solution at 70 degrees centigrade with an etch time of 22 minutes.

A Suss MA6 aligner was used to expose AZ1500 photoresist with 2-5 μm wide slots which were developed and transferred into the underlying oxide or /nitride layer using buffered-HF etching. The resist was removed from the substrates and they were placed in 40% wt KOH solution heated to 65° C. in a temperature controlled, ultrasonic bath. 5% IPA was added just before the substrates were introduced and served as a surfactant for the etching process. Complete V-grooving occurred in 5-19 mins (depending on the slot width). After the V-grooves were fully etched, the substrates were stripped of oxide (using HF) and cleaned in piranha solution (1:4 by vol. H₂O₂:H₂SO₄).

Examples of V-grooves and related structures formed in a similar way and imaged using atomic force microscopy are shown in FIG. 1. The V-groove is approximately 5 microns across and was formed using optical lithography. One of the attractions of the technique is that it allows features to be readily scaled down in size, using electron beam lithography.

c) Passivation of the V-Grooves.

The specific cluster/substrate pair which is being used determines whether or not the surface of the V-groove needs to be passivated (i.e. coated with an insulating layer in order to provide insulation between the nanowire and the substrate). For some wire/substrate combinations a Schottky contact will be formed, enabling limited isolation of the wire from the substrate. In some cases the native oxide layer on the substrate will provide sufficient isolation. If required, passivation of the V-grooves may be carried out in two ways. At present, the preferred method is to thermally oxidise the entire substrate immediately after forming the V-groove arrays. Oxidation is performed in an oxygen rich dry furnace at 1050 degrees centigrade. An oxidation period of one hour produces a 120 nm thick film of silicon dioxide. An alternative passivation method relies on sputter coated silicon nitride.

d) Deposition of the Nanowire Material.

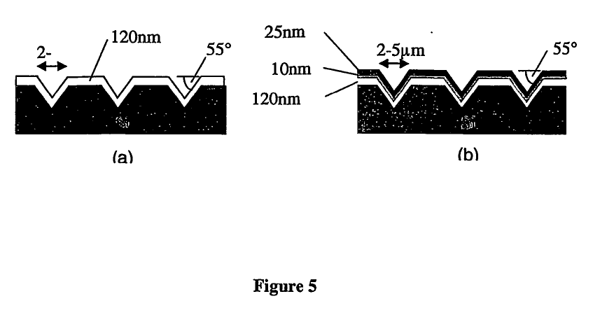

For samples on which the cluster-assembled wires are to be used as an etch mask, Ti (7 nm adhesion layer) and Au (25 nm top layer) were evaporated onto the passivated, V-grooved substrates. The layer structure of passivated and passivated/metallised V-grooved samples are shown schematically in FIG. 5. The Ti/Au layer is the material that will eventually form the nanowire (after the masking and etching steps described below).

It is noted that the coating of the V-groove surface by either or both of a passivation layer or a semiconductor/metal layer will influence the subsequent assembly of deposited clusters on the. surface, and that the passivation material, semiconductor/metal layer material and cluster material can be selected to influence the morphology of the cluster-assembled mask.

e) Cluster Formation and Deposition

Ionised clusters and/or a mass selection system may be used in a deposition system, for example incorporating a mass filter of the design of Ref [16] and cluster ionisation by a standard electron beam technique.

Our preferred apparatus is a modified version of the experimental apparatus described in Ref. [17].The metallic vapour necessary for cluster production is produced from a crucible containing Sb which is heated in a source chamber using a tungsten filament. The crucible temperature is monitored and controlled via a thermocouple mounted in the base of the crucible. Ar is fed through a flow controller and then directly into the source chamber where it assists in the condensation/aggregation process required for cluster growth. Once the crucible temperature is raised sufficiently to achieve a vapour pressure of 0.1-1.0 mbar, clusters are grown from the supersaturated metallic vapour. The cluster/gas mixture passes two stages of differential pumping (from ˜1 Torr in the source chamber down to ˜10⁻⁶ Torr in the main chamber) such that most of the gas is extracted. The beam enters the main chamber through a nozzle having a diameter of about 1 mm and an opening angle of about 0.5 degrees. At the sample, the diameter of the cluster beam is about 4 mm. In order to determine the intensity of the cluster beam, a quartz crystal deposition rate monitor is used. The samples are mounted on a movable rod and are positioned in front of the quartz deposition rate monitor during deposition.

Note that the specific range of source parameters appears not to be critical: clusters can be produced over a wide range of pressures (0.01 torr to 100 torr) and evaporation temperatures and deposited at almost any pressure from 1 torr to 10-12 torr. Any inert gas, or mixture of inert gases, can be used to cause aggregation, and any material that can be evaporated may be used to form clusters. The cluster size is determined by the interplay of gas pressure, gas type, metal evaporation temperature and nozzle sizes used to connected the different chambers of decreasing pressure.

f) Experimental Realisation of Cluster Chains to Act as a Mask

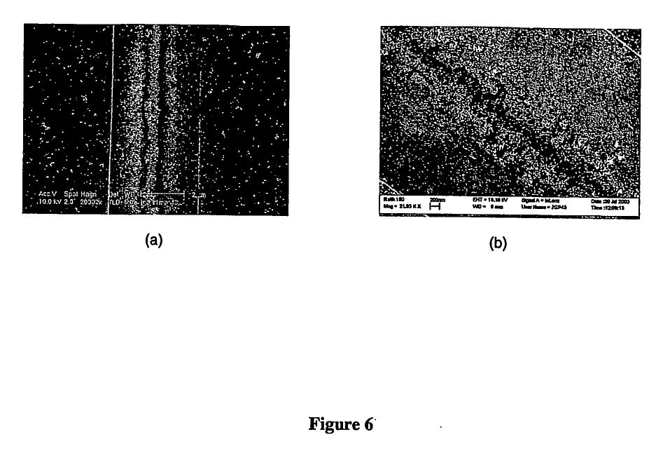

The source Ar inlet flow-rate is used to control the average momentum of the clusters. When operating the source with Ar flow-rates above 100 sccm, Sb clusters landing on 4 μm wide SiO₂ V-grooves bounce or slide until they reach the apexes where they accumulate to form wires, whilst almost all clusters landing on the plateaus (between the V-grooves) have sufficient momentum to be reflected from them. For the purposes of nanowire fabrication, the Ar flow-rate is selected to ensure that clusters landing anywhere within the ‘mouth’ of the V-groove were driven to its apex. The deposition rate for a given gas flow rate is adjusted via the temperature of the source and is monitored with a quartz crystal film thickness monitor (FTM) mounted behind the sample and in line with the cluster beam. A measured deposition rate of 0.3 A/s, with Ar flow-rate of 150 sccm, produces wires with nano-scale widths on 3 μm wide V-grooves in approximately 120 s (FIG. 6). For Sb, the crucible temperature is typically between 550° C. and 580° C. in order to achieve this deposition rate. An electronic shutter attached to the sample arm is opened in order to begin deposition onto the sample at room temperature. Following the deposition, samples are removed from the vacuum system and the cluster films are inspected using an SEM and EDX analysis.

FIG. 6 shows Field-Emission Scanning Electron Microscope (FE-SEM) images of Sb clusters deposited with Ar source inlet flow rate of 150 sccm on SiO₂ (a) and metallised/passivated Si V-grooves (b). In both FIG. 6 (a) and (b) cluster assembly has taken place at the apex of the V-groove and cluster free regions exist on the walls of the groove above the apex.

The cluster beam-spot is more intense in the centre than at the edges, and was 2 mm in diameter. At the centre of the cluster beam spot, clusters accumulate and back-up on each other at the apexes of the V-groove and the larger density of clusters means that the width of the wires formed there is larger than those formed at the edge of the beam spot. Across the entire area of the beam spot, cluster coverage on the plateaus between the V-grooves is well below the percolation threshold and this ensures that no chain of significant length is present on the surface, except at the apex of the V-groove. [18].

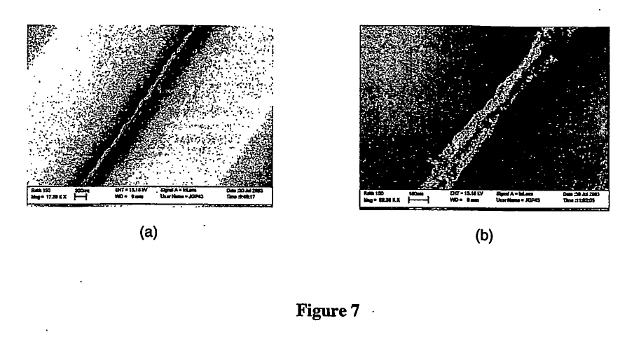

FE-SEM images of an anisotropically Ar plasma-etched Ti/Au wire are shown in FIG. 7. The Ar-plasma etch parameters used to remove the rest of material used to form the wire, as in FIG. 7, where Ar flow-rate: 70 sccm, process pressure: 0.05 mbar, DC bias: −460V and RF power: 200 W. The etch process took 270 s. Following the plasma-etch, a wet selective etch was used to remove the Sb mask. (This selective etch consisted of 100 ml deionised water, 25 g citric acid and 10 g ammonium molybdate. The immersion time was 360 s at room temperature).

The maximum and minimum widths of the wire were ˜300 nm and ˜100 nm respectively over a length exceeding 100 μm. The wire demonstrates the same selective formation properties as the Sb cluster assembled wires: following the dry etch process no parasitic conduction paths existed on the planar substrate areas or on the V-groove walls. The 120 nm thick SiO2 passivation layer was etched back 10-20 nm by the Ar plasma process—this figure could be reduced further by timing the process more precisely. Redeposition of Sb cluster material occurs on the V-groove sidewalls during the plasma etch but is not significant enough to cause masking of the metallic film there.

g) FE-SEM/Electron Dispersive Xray (EDX) Analysis of Nanowires

Energy Dispersive X-ray (EDX) analysis was performed on the Sb cluster masked samples following the Ar-plasma process and after the selective etch process. EDX scans covering the entire substrate confirmed the presence of Sb and Au prior to the selective etch, whilst peaks corresponding to Au but not Sb were recorded afterwards. It was therefore concluded that the remaining wires were Au.

h) Contact Formation

In this Invention electrical contacting to the nanowire is the final stage of the process. The contacts are formed using either optical or combined electron-beam/optical lithography stages.

Following the removal of the cluster-assembled mask, the substrate and non-contacted metallic wires are spin coated with photoresist (AZ1500 or S1805). The sample is then patterned with multiple contact pads using either optical or electron beam lithography and lift-off of a Ti/Au film. If necessary, alignment features can be written into the resist prior to contact pad patterning using scanning electron microscope imaging and electron beam lithography.

The widths of the contact pads determine the number of wires that are contacted and the contact pad separations determine the length of these wires. Hence multiple or single wires can be contacted and their I(V) characteristics determined. (By using various widths of contact pad on a single sample, the contact resistance associated with the measurement system and the contact/wire interface can be estimated and de-embedded from the wire resistance measurements).

Finally, multiple large-scale contacts can be formed in a single optical lithography stage. The sample can then be mounted in the standard I(V) test apparatus and I(V) characterisation performed in a range of temperatures, magnetic fields and in the presence of various gases.

Finally, we note that the Invention may take advantage of many forms of surface texturing and are not limited to V-grooves. FIG. 3 shows atomic force microscope images at two different resolutions of the bottom of an ‘inverted pyramid’. Inverted pyramids are formed when etching silicon using KOH and a mask or window with circular or square geometry (rather than slots as described above). It is possible to achieve inverted pyramids with very small dimensions and extremely flat walls (as in the lower image in FIG. 3 where the ridges are due to the quality of the AFM image, and are not representative of the flatness of the surface). In a preferred embodiment electron beam lithography is used to define electrical contacts at each of the four corners of a wire which runs along the apexes of the inverted pyramid, thereby allowing 4 terminal measurements of the wire. Such 4 terminal measurements may be useful for precise conductivity measurements for, for example, magnetic field or chemical sensing applications. Top and/or bottom gates may also be applied to these structures.

### EXAMPLES

The invention is further illustrated by the following examples:

### 1. Lithography Processes

Combinations of optical and Electron Beam Lithography and their use in the formation of surface features and contacts have been described in a previous patent application [9] and are hereby incorporated by reference.

### 2. Results of Cluster Deposition Experiments

Deposition of bismuth clusters onto plain SiN surfaces (or such surfaces with predefined electrical contacts) and the imaging of such cluster films using atomic force, optical and field emission scanning electron microscopy (FE-SEM) has been described in a previous patent application [9] and are hereby incorporated by reference. The FE-SEM images in that previous work show that the clusters do not diffuse and coalesce significantly on SiN: there is a limited amount of coalescence—the clusters merge very slightly into their neighbours—but in general the particles are still distinguishable. On V-grooves (see images in FIGS. 1-12 in NZ Provisional Specification 524059) there is a greater degree of coalescence of particles in the apex of V-grooves, and, in addition to devices comprising single wire-like chains, the construction of larger diameter particles and wires with diameters comprising many particles is a significant aspect of the invention.

### 3. Theory: Effect of Incident Kinetic Energy on the Detachment of Clusters After Landing

Described in detail in NZ Provisional Specification 524059. The key aspect of the proposed model for the observed bouncing/sliding of clusters is relatively old model for the bouncing of liquid droplets from surfaces. Put simply, the model suggests that clusters/droplets will bounce if the kinetic energy of the rebounding droplet is sufficient to overcome the energy of attachment which results from wetting of the surface by the clusters/droplets.
1. See p 428 in S. Sze, ‘Semiconductor Devices’ Wiley New York, 1985.
2. See p 443 in S. Sze, ‘Semiconductor Devices’ Wiley New York, 1985.
3. T. Haatainen, J. Ahopelto, Pattern transfer using step and stamp imprint lithography.Physica Secripta, 67(4), 357-360 April 2003.
4. M. Colburn, S. Johnson, M. Stewart, S. Damle, B. J. Choi, T. Bailey, M. Wedlake, T. Michaelson, S. V. Sreenivasan, J. Ekerdt and C. G. Wison, Proc. SPIE, Vol. 3676, 379, 1999.
5. D. Y. Khang, H. H. Lee, Room Tempretaure imprint lithograpgy by solvent vapour treatment, Appl. Phys.Lett, 76, no 7, 14 Feb. 2000.
6. M. Li, L. Chen, S.Chou, Direct three dimensional patterning using nanoimprint lithography, Appl. Phys Lett, 78, no. 21, pp 3322-3324, 21 May 2001.
7. W. de Heer, Rev. Mod. Phys. 65, 611 (1993)
8. I. M. Goldby et al, Rev. Sci. Inst. 68, 3327 (1997).
9. International Patent Application number PCT/NZ02/00160; NZ Patent Application number 51367, “Nanoscale Electronic Devices and Fabrication Methods”.
10. S. Tans et al Nature 393, 49 (1998).
11. H. Chopra and S. Hua, Phys. Rev. B 66, 020403 (2002).
12. C. Li et al, Appl. Phys. Lett. 76, 1333 (2000)
13. L M. Goldby et al, Appl. Phys. Lett. 69, 2819 (1996).
14. G. M. Francis et al, J. Appl. Phys. 73, 2942 (1996).
15. Similar etching techniques are used for a different type of device structure in H. Ishikuro and T. Hiramoto, Jap. J. Appl. Phys. 38, 396 (1999).
16. B. von Issendorf and R. Palmer, Rev. Sci. Inst. 70, 4497(1999)
17. B. D. Hall, PhD thesis, Ecole Polytechnique Federale de Laussanne, Switzerland (1991).
18. J. Schmelzer Jr., S. A. Brown, A. Wurl, M. Hyslop and R. J. Blaikie, Phys. Rev. Lett. 88, 226802 (2002).

1. A method of forming a pattern on or in a substrate surface comprising or including the steps of:
a) Providing a substrate;
b) modifying the substrate surface to provide a topographical feature, or identifying a topographical feature on the substrate surface;
c) preparing a plurality of particles of size between about 0.5 nm and 100 microns;
d) deposition of a plurality of the particles on the substrate surface in, or in the general vicinity of, the topographical feature;
e) formation of an arrangement of particles via accumulation of the particles, into or against or proximal to, the topographical feature;
f) removing at least a portion of the substrate by etching, the arrangement of particles acting as an etch mask.

2. A method as claimed in claim 1 wherein the size of the particles is between about 0.5 nm and 1000 nm.

3. A method as claimed in claim 1 wherein the substrate is at least partially an insulating or semiconducting material.

4. A method as claimed in in claim 1 wherein the pattern is in the form of a wire; the arrangement of particles being a substantially continuous chain of metallic clusters.

5. A method as claimed in claim 4 wherein the wire is a nanowire and the particles are nanoparticles.

6. A method as claimed in claim 1 wherein the modification includes formation of a step, depression or ridge in the substrate surface.

7. A method as claimed in claim 6 wherein the modification comprises formation of a groove having a substantially v-shaped cross-section or inverted pyramid structure running substantially between the contacts.

8. A method as claimed in claim 7 wherein the surface modification involves lithography.

9. A method as claimed in claim 8 wherein the surface modification step involves the use of etching and takes advantage of the different etch rates of crystallographic planes in the substrate material.

10. A method as claimed in claim 1 wherein the particles are composed of two or more atoms, which may or may not be of the same element.

11. A method as claimed in claim 1 wherein the accumulation of particles into or against or proximal to, the topographical feature relies upon the diffusion, sliding, bouncing or other movement of the particles across or on the surface of the substrate or any material deposited on the substrate.

12. A method as claimed in claim 3 wherein the substrate is substantially entirely an insulating or semiconductor material.

13. A method as claimed in claim 12 wherein the etching step removes substantially all of the substrate other than the masked portion thereby leaving a free-standing wire or bridge.

14. A method as claimed in claim 3 wherein the substrate is an insulating or semiconductor material with one or more surface coatings selected from one or more of a metallic and/or insulating and/or semiconducting material, and wherein one of more of the surface coatings may have been deposited before or after step b) of modifying the substrate surface.

15. A method as claimed in claim 14 wherein the etching step removes substantially entirely all of one or more of the one or more surface coatings other than the masked portion.

16. A method as claimed in 15 wherein the substrate comprises an insulating or semiconductor material coated with one or more metallic and/or semi-conducting layer(s), the metallic and/or semiconducting layer(s) being crystalline, nano- or micro-crystalline, or amorphous.

17. A method as claimed in claim 16 wherein the metallic and/or semiconducting layer(s) are formed by cluster deposition of a plurality of clusters, prior to and having a different identity to, the plurality of particles formed and deposited in steps c) and d).

18. A method as claimed in claim 16 wherein the metallic and/or semi-conducting layer(s) are homogeneous.

19. A method as claimed in claim 16 wherein the metallic and/or semi-conducting layer(s) are not homogeneous.

20. A method as claimed in claim 1 wherein the method may also include treatment of the substrate surface such as by passivation, or adding an insulating layer such as SiOx or SiN, at some point prior to any coating of the substrate with the one or more metallic and/or semiconducting layers.

21. A method as claimed in claim 14 wherein the method may also include the step of coating of the substrate surface such as by adding an insulating layer such as SiOx or SiN, or different semi-conducting layer, for the purpose of electrical insulation or prevention of oxidation of the metal or semi-conducting layer, at some point subsequent to the substrate being coated with the one or more surface coatings selected from one or more of a metallic and/or insulating and/or semiconducting material.

22. A method as claimed in claim 1 wherein the method also includes an additional lithography step or steps to provide electrical contact to the pattern.

23. A method as claimed in claim 22 wherein the additional lithography step or steps is/are subsequent to step f).

24. A method as claimed in claim 23 wherein lithography is used to form two contacts which are separated by a distance smaller than 100 microns.

25. A method as claimed in claim 24 wherein the contacts are separated by a distance less than 1000 nm.

26. A method as claimed in claim 1 wherein the particles are metallic clusters.

27. A method as claimed in claim 26 wherein the particle/nanoparticle preparation and deposition steps are via inert gas aggregation, or magnetron sputtering and aggregation, or other similar cluster preparation method, and the nanoparticles are atomic clusters made up of a plurality of atoms which may or may not be of the same element.

28. A method as claimed in claim 3 wherein the semiconductor or insulator of the substrate is selected from silicon, silicon nitride, silicon oxide, aluminium oxide, indium tin oxide, germanium, gallium arsenide or any other Ill-V semiconductor, quartz, or glass.

29. A method as claimed in claim 16 wherein the one or more surface coating is/are selected from one or more of aluminium, silicon, platinum, palladium, germanium, silver, gold, copper, iron, nickel or cobalt.

30. A method as claimed in claim 5 wherein the nanoparticles are selected from one or more of bismuth, antimony, aluminium, silicon, platinum, palladium, germanium, silver, gold, copper, iron, nickel or cobalt clusters.

31. A method as claimed in claim 26 wherein the angle of incidence of the deposition of clusters onto the substrate or the angle of the topographical feature(s) on the substrate is controlled so as to affect the density of particles or their ability to slide, stick or bounce, in or on any part or parts of the substrate.

32. A method as claimed in claim 31 wherein the kinetic energy of the particles to be deposited on the substrate is controlled by the gas pressures and nozzle diameters of an inert gas aggregation source, or magnetron sputtering and aggregation, or other similar cluster source, and/or associated vacuum system.

33. A method as claimed in claim 32 wherein the conditions are such to encourage diffusion of the nanoparticles on the substrate surface, including one or more of the conditions of temperature, surface smoothness and/or surface type and/or identity.

34. A method as claimed in any claim 1 wherein prior to deposition, one or more of the following processes may occur:
ionisation of particles,
size selection of particles,
acceleration and focussing of clusters,
the step of oxidising or otherwise passivating the surface of the v-groove (or other template) so as to modify the subsequent motion of the incident particles,
selection of particle and substrate materials and particles’ kinetic energy so as to cause the particle to bounce off a part of the substrate (for example the unmodified areas between surface modifications), thereby preventing the adherence of particles in that area of the substrate,
selection of size of surface modification (e.g. width of V-groove) and so as to control the thickness of the wire formed.

35. A method as claimed in claim 1 wherein the etching step f) results in removal of the substrate material and some or all of any coating materials (if present) in preference to the arrangement of particles.

36. A method as claimed in claim 1 wherein the etching step f) results in removal of the non-masked coating material in preference to the substrate material.

37. A method as claimed in claim 36 wherein the etching step is a plasma etching process.

38. A method as claimed in claim 1 wherein the method further includes the step of:
g) removing the etch mask.

39. (canceled)

40. A metallic or semi-conducting pattern on the surface of a substrate prepared substantially according to method claimed in claim 1.

41. A method of fabricating a device including or requiring a conduction path between two contacts formed on a substrate surface, comprising or including the steps of:
A. preparing a conducting pattern between two contacts according to a method comprising or including the steps of:
i. providing a semiconducting or insulating substrate;
ii. modifying the substrate surface to provide a topographical feature, or identifying a topographical feature on the substrate surface;
iii. preparing a plurality of clusters;
iv. deposition of a plurality of the clusters on the substrate surface in, or in the general vicinity of, the topographical feature;
v. formation of an arrangement of clusters via accumulation, of the clusters, into or against or proximal to, the topographical feature;
vi. subjecting the substrate and arrangement to an etching process, the arrangement of clusters acting as an etch mask
wherein either prior to or after step ii. one or more metallic or semiconducting layers are deposited on the substrate surface, such that the etching process removes substantially all of the one or more metallic or semiconducting layers other than the masked portion, and
wherein the process also includes, at any stage, a step of providing electrical contacts on the substrate so that once etching is complete a conducting pattern exists between the contacts; and
B. incorporating the contacts and wire into the device.

42. A method as claimed in claim 41 wherein the device includes two or more contacts and the conducting pattern is a conducting wire.

43. A method as claimed in claim 42 wherein the device is a nanoscale device, and the wire is a nanowire.

44. A method as claimed in claim 41 wherein there is an additional step in A of removing the etch mask at some point following the etching process.

45. A device including or requiring a conduction path between two contacts formed on a substrate surface prepared substantially according to the method as claimed in claim 41.

46. (canceled)
